(19) United States
(12) Patent Application Publication
(10) Pub. No.: US 2023/0317423 A1
(43) Pub. Date: Oct. 5, 2023

(54) MAGNESIUM ALUMINUM OXYNITRIDE COMPONENT FOR USE IN A PLASMA PROCESSING CHAMBER

(71) Applicant: Lam Research Corporation, Fremont, CA (US)

(72) Inventors: Pankaj HAZARIKA, Sherwood, OR (US); Joel HOLLINGSWORTH, Portland, OR (US); Matthew Brian SCHICK, Pflugerville, TX (US); Pratima G.N. RAO, Wilsonville, OR (US)

(21) Appl. No.: 18/021,757

(22) PCT Filed: Oct. 27, 2021
(86) PCT No.: PCT/US2021/056873

§ 371 Date: Feb. 16, 2023

Related U.S. Application Data
(60) Provisional application No. 63/107,722, filed on Oct. 30, 2020.

(51) Int. Cl. H01J 37/32

(52) U.S. Cl. CPC H01J 37/32467; H01J 37/32495; H01J 37/32807; H01J 2237/3341

(57) ABSTRACT

A component for use in a plasma processing chamber system is START provided. The component for use in a processing chamber system comprises a bulk component body comprising magnesium aluminum oxynitride and sintering aids. The sintering aids comprise at least one of yttria, yttrium aluminate, rare earth metal oxide, and rare earth metal aluminate.

### CROSS-REFERENCE TO RELATED APPLICATION

This application claims the benefit of priority of U.S. Application No. 63/107,722, filed Oct. 30, 2020, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In forming semiconductor devices, plasma processing chambers are used to process the substrates. Some plasma processing chambers have component parts that are eroded during plasma processing. Coatings may be used to protect the component parts. However, temperature differentials and other factors may cause the coatings to delaminate from the component part.

Several commercial and technological processes require the use of reactive fluorine species; some of these processes also involve elevated temperatures and/or high vacuum environments. For example, a chamber cleaning process may use a remote fluorine plasma. If the chamber is not allowed to sufficiently cool, plasma-facing surfaces of the chamber may be exposed to the reactive fluorine species at a temperature above 500° C. at pressures below 10 Torr. Such an environment causes corrosion/erosion of the plasma-facing surface. Components designed to survive such environments are typically made of or coated with aluminum, nickel, aluminum oxide, or aluminum nitride. Reaction products of nickel fluoride and aluminum fluoride are formed when these surfaces are exposed to reactive fluorine species. The nickel fluoride and aluminum fluoride serve to arrest further reaction with fluorine at low and moderate temperatures but pose a risk to the intended process under conditions of high temperature and/or high vacuum. The nickel fluoride and aluminum fluoride are potentially emitted (eg. evaporated, delaminated, detached) from the material surface. As the reaction proceeds, particles of nickel fluoride and aluminum fluoride can also be generated, resulting in particulate and/or chemical contamination of the intended process. These risks limit the temperature at which components can safely be exposed to reactive fluorine species to approximately 400 to 500 degrees Celsius.

### SUMMARY

To achieve the foregoing and in accordance with the purpose of the present disclosure, a component for use in a plasma processing chamber system is provided. The component comprises a bulk component body comprising magnesium aluminum oxynitride and sintering aids, wherein the sintering aids comprise at least one of yttria, yttrium aluminate, rare earth metal oxide, and rare earth metal aluminate.

In another manifestation, a method for forming a component for use in a processing chamber is provided. A bulk component body is sintered from a sintering powder comprising sintering aids and a mixture of powders that form magnesium aluminum oxynitride when sintered together, wherein the sintering is at a temperature of at least 1000° C. to form a component comprising magnesium aluminum oxynitride and sintering aids, wherein the sintering aids comprise at least one of yttria, yttrium aluminate, rare earth metal oxide, and rare earth metal aluminate.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2 is a schematic view of a pedestal used provided in an embodiment.

FIG. 3 is a schematic view of a plasma processing chamber that may be used in an embodiment.

FIG. 4 is a pseudo-ternary diagram.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Embodiments provide a component for a plasma processing chamber that is resistant to erosion when exposed to a reactive fluorine from a remote fluorine plasma at a temperature above 500° C. and a pressure below 10 Torr. Such a component may comprise magnesium aluminum oxynitride and sintering aids.

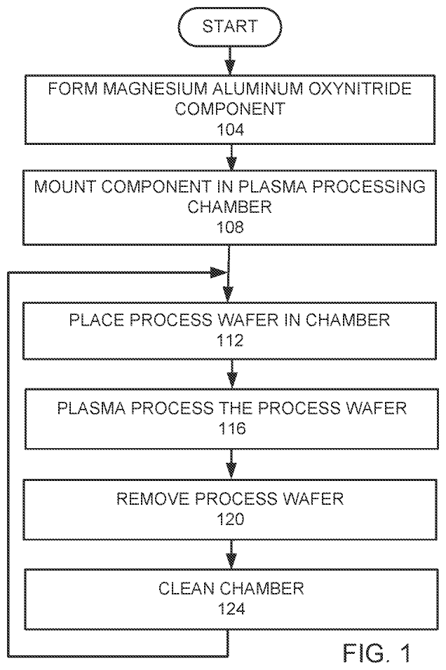

To facilitate understanding, FIG. 1 is a high-level flow chart of a process used in an embodiment. A bulk component body is provided (step 104). The bulk component body comprises magnesium aluminum oxynitride and sintering aids. The bulk component body may be formed by sintering a sintering powder. The use of the term “bulk component body” means that the entire component body is formed from a single sintered powder of magnesium aluminum oxynitride and sintering components in contrast to a component body formed by multiple laminated layers of different materials. In an embodiment, a sintering powder of a mixture of sintering aid powders and a mixture of powders that form magnesium aluminum oxynitride when sintered together is provided for forming a bulk component body. The sintering aids may be at least one of yttria, yttrium aluminate, rare earth metal oxide, and rare earth metal aluminate. In some cases, the sintering aid includes an oxide of a rare earth element such as yttrium or lanthanum. In some cases, the sintering aid includes an oxide of an alkaline earth metal (e.g., group 2 metal) such as calcium, magnesium, etc., or of a rare earth metal, such as yttrium, lanthanum, etc. Example materials that may be used for the sintering aid include, but are not limited to, calcium oxide (e.g., CaO), yttrium oxide (e.g., Y₂O₃), lanthanum oxide (e.g., La₂O₃), and combinations thereof. The sintering aid may be provided at a concentration of about 5-10% (by weight) of the powder. The powders that form magnesium aluminum oxynitride when sintered together may comprise a powder MgAl₂O₄ or alumina-magnesia mixed with a powder of aluminum nitride or aluminum oxynitride. The powders that form magnesium aluminum oxynitride when sintered together may further comprise aluminum oxide. In other embodiments, the powders that form magnesium aluminum oxynitride is magnesium aluminum oxynitride formed into spinel crystals and then ground to form a powder. In this embodiment, the sintering powder is a powder mixture of MgAl₂O₄ powder, oxynitride powder, and yttria. In this embodiment, using yttria as a sintering aid improves the corrosion resistance of the final part. The sintering powder is placed in a mold.

In this embodiment, the sintering that is used to form the bulk component body from sintering powder may use one of various sintering processes, such as cold pressed, hot pressed, warm pressed, hot isostatic press, green sheet, and spark plasma sintering. In some embodiments, the sintering powder may be heated to at least 1000° C. for at least 2 hours. In some embodiments, the sintering is heated for at least 1 day. In this embodiment, pressure is provided in a range of about 28 megapascals (MPa) to about 69 MPa. In this embodiment, the powder is heated to a temperature in the range of about 1100° C. to 1700° C.

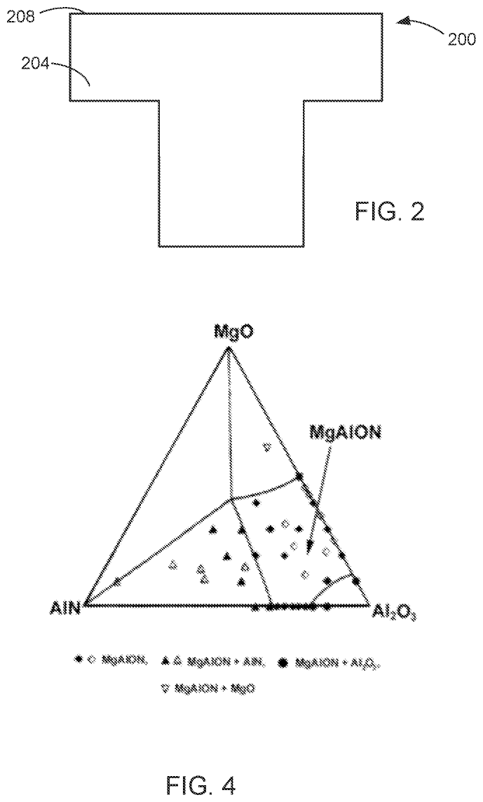

FIG. 2 is a schematic view of a bulk component body 204 of a component 200. In this example, the component 200 is a pedestal. In this embodiment, the bulk component body 204 is formed from a dielectric ceramic of sintered magnesium aluminum oxynitride. The bulk component body 204 has a surface 208 that is exposed to a reactive halogen species. In some embodiments, the surface 208 is a plasma facing surface. A plasma facing surface is a surface that is either exposed to a plasma during wafer or substrate processing or is exposed to a reactive halogen species at high temperature and low pressure. The reactive halogen species may be formed from a remote plasma or thermally reactive fluorine.

In various embodiments, the bulk component body 204 is machined and polished after sintering. The machining may be at least one of drilling, grinding, water-jet cutting, media blasting, and laser ablation.

The component 200 is mounted in a plasma processing chamber (step 108). In this embodiment, the component 200 may be used as a pedestal for supporting a process wafer or substrate in a plasma processing chamber.

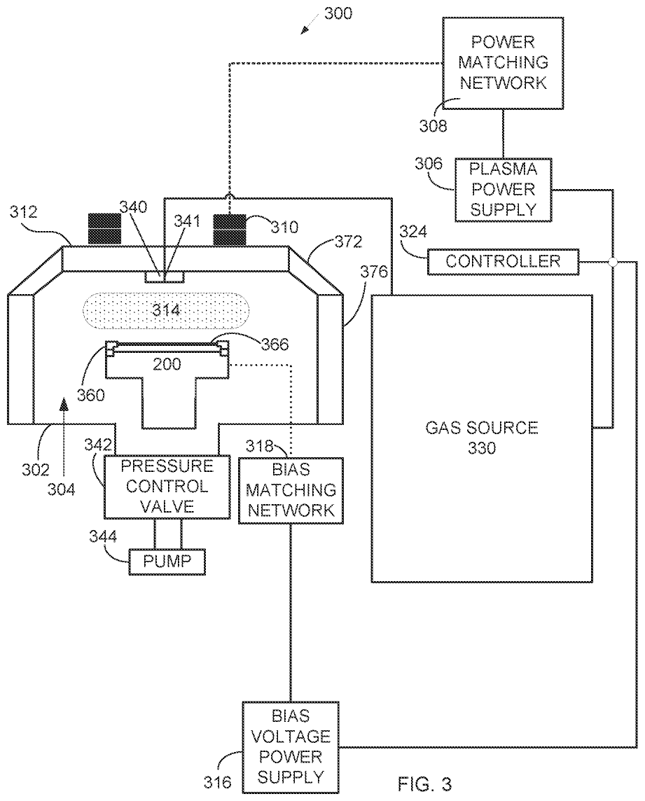

To facilitate understanding, FIG. 3 schematically illustrates an example of a plasma processing chamber system 300 that may be used in an embodiment. The plasma processing chamber system 300 includes a plasma reactor 302 having a plasma processing chamber 304 therein. A plasma power supply 306, tuned by a power matching network 308, supplies power to a transformer coupled plasma (TCP) coil 310 located near a dielectric inductive power window 312 to create a plasma 314 in the plasma processing chamber 304 by providing an inductively coupled power. A pinnacle 372 extends from a chamber wall 376 of the plasma processing chamber 304 to the dielectric inductive power window 312 forming a pinnacle ring. The pinnacle 372 is angled with respect to the chamber wall 376 and the dielectric inductive power window 312. For example, the interior angle between the pinnacle 372 and the chamber wall 376 and the interior angle between the pinnacle 372 and the dielectric inductive power window 312 may each be greater than 90° and less than 180°. The pinnacle 372 provides an angled ring near the top of the plasma processing chamber 304, as shown. The TCP coil (upper power source) 310 may be configured to produce a uniform diffusion profile within the plasma processing chamber 304. For example, the TCP coil 310 may be configured to generate a toroidal power distribution in the plasma 314. The dielectric inductive power window 312 is provided to separate the TCP coil 310 from the plasma processing chamber 304 while allowing energy to pass from the TCP coil 310 to the plasma processing chamber 304. A wafer bias voltage power supply 316 tuned by a bias matching network 318 provides power to component 200 to set the bias voltage when a process wafer 366 is placed on the component 200. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve the desired process performance. For example, in one embodiment, the plasma power supply 306 may supply the power in a range of 50 to 5000 Watts, and the wafer bias voltage power supply 316 may supply a bias voltage of in a range of 20 to 2000 volts (V). In addition, the TCP coil 310 and/or the component 200 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing chamber 304 through a gas inlet, such as a gas injector 340. The gas injector 340 has at least one borehole 341 to allow gas to pass through the gas injector 340 into the plasma processing chamber 304. The gas injector 340 may be located in any advantageous location in the plasma processing chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process chamber 304. More preferably, the gas injector is mounted to the dielectric inductive power window 312. The gas injector may be mounted on, mounted in, or form part of the power window. The process gases and by-products are removed from the plasma process chamber 304 via a pressure control valve 342 and a pump 344. The pressure control valve 342 and pump 344 also serve to maintain a particular pressure within the plasma processing chamber 304. The pressure control valve 342 can maintain a pressure of less than 1 Torr during processing. An edge ring 360 is placed around a top part of the component 200. The gas source/gas supply mechanism 330 is controlled by the controller 324. A Kiyo, Strata, or Vector by Lam Research Corp. of Fremont, CA, may be used to practice an embodiment.

A process wafer 366 is placed in the plasma processing chamber 304 (step 112). The process wafer 366 is placed on the component 200, as shown. A plasma process is applied to the process wafer 366 (step 116). In this example, the plasma process of the process wafer 366 is used to provide an etch of part of a stack on the process wafer 366, such as for etching a tungsten containing layer in the stack. In this embodiment, the plasma process would heat the pedestal to a temperature above 550° C. In addition, the plasma process deposits residue on the interior of the plasma processing chamber. After the plasma processing of the process wafer 366, the process wafer 366 is removed from the plasma processing chamber 304 (step 120). The plasma processing chamber 304 is cleaned to remove deposited residue (step 124). In this embodiment, a reactive fluorine from a remote fluorine plasma is used to clean the interior of the plasma processing chamber 304. A pressure in the range of 1 milliTorr (mTorr) to 10 Torr is provided. The component 200 has not sufficiently cooled and remains at a temperature above 500° C. After the cleaning is completed, a new process wafer 366 may be placed in the plasma processing chamber 304 (step 112) to begin a new cycle.

It has been found that components in the prior art when exposed to reactive fluorine species at temperatures above 500° C. and pressures below 10 Torr form nickel fluoride or aluminum fluoride particles that act as contaminants. Allowing the component 200 more time to cool causes a decrease in throughput. However, magnesium aluminum oxynitride components with sintering aids are more resistant to corrosion/erosion and the formation of contaminants in such conditions. It is believed that the presence of nitride makes the component 200 more resistant to thermal shock and coefficient of thermal expansion (CTE)-compatible. In some embodiments, the reactive fluorine may be created by a thermal process instead of being from a remote plasma. In addition, the addition of nitride provides improved mechanical properties to allow the bulk component to be made of magnesium aluminum oxynitride, instead of having only a layer of magnesium aluminum oxide.

In various embodiments, the component 200 may be other parts of a plasma processing chamber 304, such as confinement rings, edge rings, the electrostatic chuck, ground rings, chamber liners, door liners, the pinnacle, a showerhead, a dielectric power window, gas injectors, edge rings, ceramic transfer arms, or other components. Other components of other types of plasma processing chambers may be used. Examples of other types of plasma processing chambers in which the component 200 may be used are capacitively coupled plasma processing chambers and bevel plasma processing chambers. The component 200 may be plasma exclusion rings on a bevel etch chamber In another example, the plasma processing chamber may be a dielectric processing chamber or conductor processing chamber.

In some embodiments, the component is sintered from powder comprising magnesium aluminum oxynitride with a spinel phase. In other embodiments, a set of reagents are chosen and prepared in proportions calculated to produce magnesium aluminum oxynitride spinel. In a preferred embodiment, the mixture of reagents comprises magnesium aluminate spinel, aluminum nitride, and a sintering aid. Other embodiments include mixtures of aluminum oxide, magnesium oxide, and aluminum nitride; mixtures of aluminum oxynitride and magnesium oxide; mixtures of magnesium aluminate spinel and metallic aluminum, to which an excess of nitrogen gas is supplied during high-temperature processing to carry out nitridation prior to or simultaneous with sintering; mixtures of magnesium oxide and aluminum nitride, to which a controlled amount of oxygen is supplied during high temperature processing so as to partially oxidize the mixture, etc.

Other methods may be used to form a component body out of magnesium aluminum oxynitride with the spinel phase. For example, an additive manufacturing process, such as 3D printing of a magnesium aluminum oxynitride with spinel phase powder may be used to form a component body. In some embodiments, the additive manufacturing may use localized heating to form the component body. In other embodiments, additive manufacturing may be used to form a green component body. The green component body is then fired.

In some embodiments, other reactive halogen species may be used in place of reactive fluorine species. When the component 200 is exposed to reactive fluorine or another reactive halogen, the fluorine may replace oxygen and other components leaving a magnesium fluoride layer. The magnesium fluoride is stable and is less likely to form particles than nickel fluoride or aluminum fluoride. The magnesium fluoride layer provides a barrier to further fluorine attack. The sintering aid limits grain boundary growth. The sintering aid acts as a barrier to prevent one grain from absorbing another grain. In some embodiments, the magnesium aluminum oxide spinel component is transparent so that the component may be used as a window or viewport.

In various embodiments, the powders that form magnesium aluminum oxynitride when sintered together comprise between 2% to 17% Mg by weight and 0.2% to 6% N by weight. Therefore, the ratio of Mg to N by weight is in the range from 30:1 to 3:10. In some embodiments, the molar ratio of magnesium to nitrogen in the bulk component body is in the range of 2:1 to 4:1. In these embodiments, the remaining powders that form magnesium aluminum oxynitride when sintered together comprise Al and O. In some embodiments, a powdered magnesium aluminum oxynitride (MgAlON) in the spinel phase is used as one of the powders that form magnesium aluminum oxynitride when sintered together. In other embodiments, the powders that form magnesium aluminum oxynitride when sintered together comprise a powder of MgAl₂O₄ mixed with enough aluminum nitride (AlN) to provide the above percentage of nitrogen with respect to magnesium. Aluminum oxide (Al₂O₃) powder is added so that both the Mg and N are within the above percentage ranges. In some embodiments, the powders that form magnesium aluminum oxynitride when sintered together are mixed with the sintering aids and an organic binder is used to form granules where the granules include a uniform mixture of the sintering powder. In some embodiments, at least two-thirds of the bulk component body by volume must have at least 10% Mg by mole fraction.

In some embodiments, the magnesium aluminum oxynitride of the component would have a phase, such as [(AlN)_{X}·(Al₂O₃)_{1-X}]_{Y}·[Al₂O₃·MgO]_{1-Y} with 0.30≤X≤0.37 and with 0.1≤Y≤0.9. In these embodiments, the molar ratio of N to Mg would be (X*Y):(1-Y). The molar ratio of AlON:AlMg-spinel would be Y:(1-Y).

In various embodiments, when formulating a powder mixture to form a ceramic with this fluorine resistance, proportions of raw materials are chosen such that the phases formed are largely resistant to fluorine. For example, FIG. 4 is a pseudo-ternary diagram from X. Wang, ‘Synthesis of AlON and MgAlON Ceramics and Their Chemical Corrosion Resistance’, Ph.D. dissertation, Materialvetenskap, Stockholm, 2001, which is incorporated by reference. In FIG. 4, vertices represent pure AlN, pure Al₂O₃, and pure MgO. Points other than the vertices represent blends of these three raw materials, and regions are labeled according to the phases observed after reactions are complete, for compositions with those proportions. The hollow symbols represent experimental data in the published literature using MgO as raw material. The solid symbols represent experimental data in published literature using MgAl₂O₄ as raw material. Two regions of interest in such a diagram represent proportions of raw material that produce a single spinel phase and proportions that produce a mixture of spinel and MgO (periclase).

Because periclase MgO displays adequate fluorine resistance, ceramics with a mixture of spinel and periclase have benefits comparable to phase-pure spinel. Whether or not periclase functions as a sintering aid, additional raw materials can then be added to the powder mixture, especially if they are chosen so as to not cause unwanted reactions. For example, if a small mole fraction of yttria (Y₂O₃) were added as a sintering aid, this would react with Al₂O₃, and either enough additional Al₂O₃ should be included in the formulation to compensate, or a region of the phase diagram should be chosen such that the desired region extends significantly in the direction facing away from the Al₂O₃ vertex of the pseudo-ternary diagram.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A component for use in a processing chamber system, comprising:
a bulk component body comprising magnesium aluminum oxynitride and sintering aids, wherein the sintering aids comprise at least one of yttria, yttrium aluminate, rare earth metal oxide, and rare earth metal aluminate.

2. The component, as recited in claim 1, wherein the magnesium aluminum oxynitride comprises MgAl₂O₄ and aluminum oxynitride.

3. The component, as recited in claim 2, wherein a molar ratio of magnesium to nitrogen in the bulk component body is in a range of 30:1 to 3:10.

4. The component, as recited in claim 2, wherein a molar ratio of magnesium to nitrogen in the bulk component body is in a range of 2:1 to 4:1.

5. The component, as recited in claim 1, wherein the component is exposed to a reactive halogen species when the component is at a temperature of at least 500° C.

6. The component, as recited in claim 1, wherein the bulk component body forms part of at least one of a liner, a pinnacle, a dielectric power window, a showerhead, an electrostatic chuck, and a pedestal, and wherein the component is exposed to a reactive halogen species when the component is at a temperature of at least 500° C.

7. The component, as recited in claim 1, wherein the magnesium aluminum oxynitride is in a form of [(AlN)_{X}·(Al₂O₃)_{1-X}]_{Y}·[Al₂O₃·MgO]_{1-Y} with 0.30≤X≤0.37 and with 0.1≤Y≤0.9.

8. A method for forming a component for use in a processing chamber, wherein the method comprises:
sintering a bulk component body of a sintering powder comprising sintering aids and a mixture of powders that form magnesium aluminum oxynitride when sintered together, wherein the sintering is at a temperature of at least 1000° C. to form a component comprising magnesium aluminum oxynitride and sintering aids, wherein the sintering aids comprise at least one of yttria, yttrium aluminate, rare earth metal oxide, rare earth metal aluminate, and magnesium oxide.

9. The method, as recited in claim 8, wherein the sintering powder has a molar ratio of magnesium to nitrogen in a range of 30:1 to 3:10.

10. The method, as recited in claim 8, wherein the sintering powder has a molar ratio of magnesium to nitrogen in a range of 2:1 to 4:1.

11. The method, as recited in claim 8, wherein the mixture of powders that form magnesium aluminum oxynitride when sintered together, comprises a powder of MgAl₂O₄ or alumina-magnesia and a powder of aluminum nitride or aluminum oxynitride.

12. The method, as recited in claim 8, wherein the magnesium aluminum oxynitride is in a form of [(AlN)_{X}·(Al₂O₃)_{1-X}]_{Y}·[Al₂O₃·MgO]_{1-Y} with 0.30≤X≤0.37 and with 0.1≤Y≤0.9.

13. A component made by the method of claim 8.
